(19) United States
(12) Patent Application Publication
(10) Pub. No.: US 2025/0088161 A1
(43) Pub. Date: Mar. 13, 2025

(54) AMPLIFIER CIRCUIT AND COMMUNICATION DEVICE

(71) Applicant: Murata Manufacturing Co., Ltd., Nagaokakyo-shi (JP)

(72) Inventor: Isao TAKENAKA, Nagaokakyo-shi (JP)

(73) Assignee: Murata Manufacturing Co., Ltd., Nagaokakyo-shi (JP)

(21) Appl. No.: 18/959,732

(22) Filed: Nov. 26, 2024

Related U.S. Application Data
(63) Continuation of application No. PCT/JP2023/007835, filed on Mar. 2, 2023.

(30) Foreign Application Priority Data
Jun. 2, 2022 (JP) 2022-090115

(51) Int. Cl. H03F 3/68; H03F 3/24; H03H 7/42

(52) U.S. Cl. CPC H03F 3/68; H03F 3/24; H03H 7/42

(57) ABSTRACT

An amplifier circuit includes a high frequency input terminal and a high frequency output terminal, amplifiers, an output transformer having an input-side coil and an output-side coil, inductors, and a bypass capacitor. An output end of the amplifier is connected to one end of the input-side coil and one end of the inductor. An output end of the amplifier is connected to the other end of the input-side coil and one end of the inductor. The other end of the inductor, the other end of the inductor, and one end of the bypass capacitor are connected to a midpoint of the input-side coil. One end of the output-side coil is connected to the high frequency output terminal.

### CROSS-REFERENCE TO RELATED APPLICATIONS

This is a continuation application of PCT/JP2023/007835, filed on Mar. 2, 2023, designating the United States of America, which is based on and claims priority to Japanese Patent Application No. JP 2022-090115 filed on Jun. 2, 2022. The entire contents of the above-identified applications, including the specifications, drawings and claims, are incorporated herein by reference in their entirety.

### TECHNICAL FIELD

The present disclosure relates to an amplifier circuit and a communication device.

### BACKGROUND ART

Patent Document 1 (FIG. 8 thereof) discloses a differential amplification type amplifier circuit having a first amplifier, a second amplifier, a first transformer (input transformer), and a second transformer (output transformer). One end of the output-side coil of the input transformer is connected to the input end of the first amplifier, and the other end of the output-side coil is connected to the input end of the second amplifier. One end of the input-side coil of the output transformer is connected to the output end of the first amplifier, and the other end of the input-side coil is connected to the output end of the second amplifier.

Patent Document 2 discloses a harmonic wave suppression circuit connectable to a transformer. A series connection circuit of two capacitors and an inductor is connected between one end and the other end of the input-side coil of the transformer.

### CITATION LIST

### Patent Documents

Patent Document 1: Japanese Unexamined Patent Application Publication No. 2008-199282
Patent Document 2: U.S. Patent Application Publication No. 2017/0201223

### SUMMARY OF DISCLOSURE

### Technical Problem

For example, as a configuration in which a power supply voltage or a bias voltage is supplied to the first amplifier and the second amplifier of the amplifier circuit disclosed in Patent Document 1, a configuration in which the power supply voltage or the bias voltage is supplied to the midpoint of the input-side coil or the output-side coil is assumed. In such a case, by providing the amplifier circuit disclosed in Patent Document 1 with a bypass capacitor between a power supply voltage supply terminal or a bias voltage supply terminal connected to the midpoint and the ground, and by adding the LC series resonance circuit disclosed in Patent Document 2, it is possible to achieve a small-sized amplifier circuit in which a power supply voltage or a bias voltage with suppressed high frequency noise is supplied.

However, in the case of the configuration in which the LC series resonance circuit disclosed in Patent Document 2 is added to the amplifier circuit disclosed in Patent Document 1, there is a problem that the impedance in a low frequency band corresponding to the signal bandwidth of a high frequency signal increases, and a so-called memory effect becomes significant, so that the ACLR (Adjacent Channel Leakage Power Ratio) deteriorates.

The present disclosure is made to solve the above problem, and a feature of the present disclosure is to provide a differential amplification type amplifier circuit and communication device in which the impedance in a low frequency band is reduced.

### Solution to Problem

To achieve the above feature, an amplifier circuit according to the present disclosure includes: a high frequency input terminal and a high frequency output terminal; a first amplifying element and a second amplifying element; an output transformer having a first input-side coil and a first output-side coil; a first inductor and a second inductor; and a first bypass capacitor. An output end of the first amplifying element is connected to one end of the first input-side coil and one end of the first inductor. An output end of the second amplifying element is connected to the other end of the first input-side coil and one end of the second inductor. The other end of the first inductor, the other end of the second inductor, and one end of the first bypass capacitor are connected to the first input-side coil. One end of the first output-side coil is connected to the high frequency output terminal. The other end of the first bypass capacitor and the other end of the first output-side coil are connected to a ground.

### Advantageous Effects of Disclosure

According to the present disclosure, it is possible to provide a differential amplification type amplifier circuit and communication device in which the impedance in a low frequency band is reduced.

### BRIEF DESCRIPTION OF DRAWINGS

FIG. 1 is a circuit configuration diagram of an amplifier circuit and a communication device according to an embodiment.

FIG. 2 is a circuit configuration diagram of an amplifier circuit according to Variation 1.

FIG. 3 is a circuit configuration diagram of an amplifier circuit according to Variation 2.

FIG. 4 is a circuit configuration diagram of an amplifier circuit according to a comparative example.

FIG. 5 is a graph showing frequency characteristics of the impedances of the amplifier circuits according to the embodiment and the comparative example.

FIG. 6A is a graph showing the ACLR of the amplifier circuit according to the comparative example.

FIG. 6B is a graph showing the ACLR of the amplifier circuit according to the embodiment.

FIG. 7A is a circuit configuration diagram of an amplifier circuit according to Variation 3.

FIG. 7B is a circuit configuration diagram of an amplifier circuit according to Variation 4.

FIG. 8 is a plan view and a sectional view of the amplifier circuit according to the embodiment.

### DESCRIPTION OF EMBODIMENTS

Embodiments of the present disclosure will be described below with reference to the drawings. It should be noted that all the embodiments described below are comprehensive or specific examples. The numerical values, shapes, materials, components, arrangement of components, connection forms and the like shown in the following embodiments are examples and are not intended to limit the present disclosure. Among the components in the following examples and variations, component(s) not described in the independent claims are described as optional component(s). Also, the size or size ratio of the components shown in the drawings is not necessarily strictly illustrated. In each drawing, substantially identical components are denoted by the same reference signs, and duplicate descriptions may be omitted or simplified.

In the present disclosure, the terms indicating relationships between elements, such as “parallel” and “orthogonal”, and the terms indicating the shape of elements, such as “rectangular”, as well as numerical ranges not only represent strict meanings, but also include substantially equivalent ranges, for example, with errors of several percent.

In the present disclosure, the term “connected” includes not only assuming directly connected by connection terminals and/or wiring conductors, but also assuming electrically connected via other circuit elements. Further, the expression “connected between A and B” means “connected to both A and B on a path connecting A and B”.

In the present disclosure, the expression “in plan view of the substrate” means viewing a substrate and circuit elements mounted on the substrate orthographically projected onto a plane parallel to the main surface of the substrate.

In the component arrangement of the present disclosure, the expression “a component is disposed on the substrate” includes that the component is disposed on the main surface of the substrate and that the component is disposed inside the substrate. The expression “a component is disposed on the main surface of the substrate” includes that the component is disposed above the main surface without contacting the main surface (for example, a component is stacked on another component disposed in contact with the main surface) in addition to that the component is disposed in contact with the main surface of the substrate. The expression “a component is disposed on the main surface of the substrate” may also include that the component is disposed in a recessed portion formed in the main surface. The expression “a component is disposed in the substrate” includes that the entire component is disposed between both main surfaces of the substrate but a portion of the component is not covered by the substrate and that only a portion of the component is disposed in the substrate, in addition to that the component is encapsulated in the module substrate.

In the present disclosure, the term “path” means a transmission line composed of a wire through which a high frequency signal propagates, electrodes directly connected to the wire, terminals directly connected to the wire or the electrodes, and/or the like.

In the present disclosure, the expression “the component A is arranged in series in the path B” means that both the signal input end and the signal output end of the component A are connected to the wire, the electrodes, or the terminals constituting the path B.

### Embodiments

### [1. Circuit Configuration of Amplifier Circuit and Communication Device]

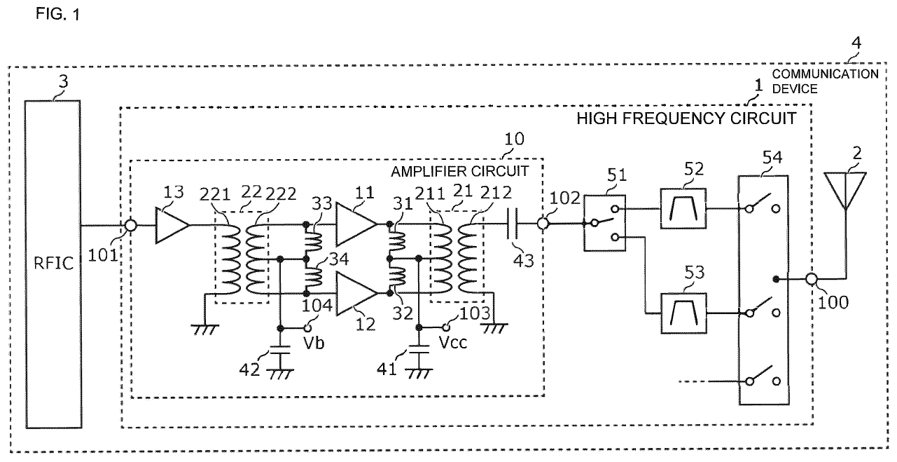

The circuit configuration of an amplifier circuit 10 and a communication device 4 according to an embodiment will be described with reference to FIG. 1. FIG. 1 is a circuit configuration diagram of the amplifier circuit 10 and the communication device 4 according to the embodiment.

### [1.1 Circuit Configuration of Communication Device 4]

First, the circuit configuration of the communication device 4 will be described. As shown in FIG. 1, the communication device 4 according to the present embodiment includes a high frequency circuit 1, an antenna 2, and an RF signal processing circuit (RFIC: Radio Frequency Integrated Circuit) 3.

The high frequency circuit 1 transmits a high frequency signal between the antenna 2 and the RFIC 3. The detailed circuit configuration of the high frequency circuit 1 will be described later.

The antenna 2 is connected to an antenna connection terminal 100 of the high frequency circuit 1, and transmits the high frequency signal outputted from the high frequency circuit 1. The antenna 2 may also receive a high frequency signal from the outside and output the received high frequency signal to the high frequency circuit 1.

The RFIC 3 is an example of a signal processing circuit for processing high frequency signals. Specifically, the RFIC 3 processes a transmission signal inputted from a baseband signal processing circuit (BBIC, not shown) by up-conversion or the like, and outputs a transmission signal generated by the signal processing to a transmission path of the high frequency circuit 1. The RFIC 3 may also processes a received signal inputted via a reception path of the high frequency circuit 1 by down-conversion or the like, and outputs a received signal generated by the signal processing to the BBIC. The RFIC 3 has a control unit for controlling switches, amplifiers and the like of the high frequency circuit 1. Note that a part or all of the functions as the control unit of the RFIC 3 may alternatively be implemented outside the RFIC 3, for example, in the BBIC or in the high frequency circuit 1.

The RFIC 3 also has a function as a control unit for controlling a power supply voltage Vcc and a bias voltage Vb to be supplied to each amplifier of the amplifier circuit 10. Specifically, the RFIC 3 outputs a digital control signal to a power supply circuit (not shown) and a bias circuit (not shown). The power supply circuit and the bias circuit may also be disposed in the high frequency circuit 1 or the amplifier circuit 10. The power supply voltage Vcc controlled by the digital control signal is supplied from the power supply circuit to each amplifier of the amplifier circuit 10, and the bias voltage Vb controlled by the digital control signal is supplied from the bias circuit to each amplifier of the amplifier circuit 10.

The RFIC 3 functions as a control unit for controlling the connection of switches 51 and 54 of the high frequency circuit 1 based on the communication band (frequency band) to be used.

Note that, in the communication device 4 according to the present embodiment, the antenna 2 is not an essential component.

### [1.2 Circuit Configuration of High Frequency Circuit 1 and Amplifier Circuit 10]

Next, the circuit configuration of the high frequency circuit 1 will be described. As shown in FIG. 1, the high frequency circuit 1 includes an amplifier circuit 10, filters 52 and 53, the switches 51 and 54, and the antenna connection terminal 100.

The amplifier circuit 10 amplifies high frequency transmission signals (hereinafter referred to as transmission signals) of band A and band B inputted from a high frequency input terminal 101. The high frequency circuit 1 may include, instead of the amplifier circuit 10, a first amplifier circuit for amplifying the transmission signal of the band A and a second amplifier circuit for amplifying the transmission signal of the band B.

In the present embodiment, each of the band A and band B is a frequency band predefined by a standardization organization or the like (for example, 3GPP (registered trademark) (3rd Generation Partnership Project), IEEE (Institute of Electrical and Electronics Engineers) and the like) for a communication system built using RAT (Radio Access Technology). In the present embodiment, the communication systems that can be used include, but are not limited to, a 4G (4th Generation)-LTE (Long Term Evolution) system, a 5G (5th Generation)-NR (New Radio) system, and a WLAN (Wireless Local Area Network) system.

The filter 52 is connected between the switches 51 and 54, and passes, among the transmission signals amplified by the amplifier circuit 10, the transmission signals in the transmission band of the band A. The filter 53 is connected between the switches 51 and 54, and passes, among the transmission signals amplified by the amplifier circuit 10, the transmission signal in the transmission band of the band B.

Each of the filters 52 and 53 may constitute a duplexer together with a reception filter, or may be a single filter for transmitting signals by TDD (Time Division Duplex) system. Assuming each of the filters 52 and 53 is a TDD filter, a switch for switching between transmission and reception is disposed in at least one of the preceding and succeeding stages of the single filter.

The switch 51 has a common terminal, a first selection terminal, and a second selection terminal. The common terminal is connected to a high frequency output terminal 102 of the amplifier circuit 10. The first selection terminal is connected to the filter 52, and the second selection terminal is connected to the filter 53. In such a connection configuration, the switch 51 switches the connection between the amplifier circuit 10 and the filter 52, and the connection between the amplifier circuit 10 and the filter 53.

The switch 54 is an example of an antenna switch. The switch 54 is connected to the antenna connection terminal 100, switches the connection and disconnection between the antenna connection terminal 100 and the filter 52, and switches the connection and disconnection between the antenna connection terminal 100 and the filter 53.

The high frequency circuit 1 may include a receiving circuit for transmitting the received signal received from the antenna 2 to the RFIC 3. In such a case, the high frequency circuit 1 includes a low-noise amplifier and a reception filter.

An impedance matching circuit may be disposed between the high frequency output terminal 102 and the antenna connection terminal 100.

With the above circuit configuration, the high frequency circuit 1 can transmit or receive the high frequency signal of either of the band A and band B. Further, the high frequency circuit 1 can perform at least one of simultaneous transmission, simultaneous reception, and simultaneous transmission and reception of the high frequency signals of band A and band B.

Note that it is sufficient for the high frequency circuit 1 according to the present disclosure to have at least the amplifier circuit 10 of the circuit configuration shown in FIG. 1.

Here, the circuit configuration of the amplifier circuit 10 will be described in detail.

As shown in FIG. 1, the amplifier circuit 10 includes amplifiers 11 and 12, a preamplifier 13, an output transformer 21, an input transformer 22, bypass capacitors 41 and 42, a capacitor 43, inductors 31, 32, 33 and 34, the high frequency input terminal 101, the high frequency output terminal 102, a Vcc terminal 103, and a Vb terminal 104. The amplifier circuit 10 according to the present embodiment is a differential amplification type amplifier circuit having the amplifiers 11 and 12.

The high frequency input terminal 101 is connected to the RFIC 3. The high frequency output terminal 102 is connected to the antenna connection terminal 100 via the switches 51 and 54 and the filters 52 and 53. The Vcc terminal 103 is an example of a power supply voltage supply terminal, and is connected to a power supply circuit (not shown) that outputs the power supply voltage Vcc. The Vb terminal 104 is an example of a bias voltage supply terminal, and is connected to a bias circuit (not shown) that outputs the bias voltage Vb. Each of the high frequency input terminal 101, the high frequency output terminal 102, the antenna connection terminal 100, the Vcc terminal 103, and the Vb terminal 104 may be a metal conductor such as a metal electrode or a metal bump, or may be a point (node) on a metal wiring.

The amplifier 11 is an example of a first amplifying element. The amplifier 11 amplifies the high frequency balanced signal outputted from one end of the output-side coil 222, and outputs a first high frequency balanced signal. The amplifier 12 is an example of a second amplifying element. The amplifier 12 amplifies the high frequency balanced signal outputted from the other end of the output-side coil 222, and outputs a second high frequency balanced signal.

Each of the amplifiers 11 and 12 has an amplification transistor. The amplification transistor is, for example, a bipolar transistor such as an HBT (Heterojunction Bipolar Transistor) or a field effect transistor such as a MOSFET (Metal-Oxide-Semiconductor Field Effect Transistor). Assuming the amplification transistor is a bipolar transistor, the input end of the amplifier 11 becomes, for example, a base end of the bipolar transistor, and the output end of the amplifier 11 becomes, for example, a collector end of the bipolar transistor. Assuming the amplification transistor is a field effect transistor, the input end of the amplifier 11 becomes, for example, a gate end of the field effect transistor, and the output end of the amplifier 11 becomes, for example, a drain end of the field effect transistor.

The preamplifier 13 amplifies the transmission signal(s) of the band A and/or band B inputted from the high frequency input terminal 101.

The input transformer 22 is an example of a first input transformer, and includes an input-side coil 221 and an output-side coil 222.

The input-side coil 221 is an example of a second input-side coil. One end of the input-side coil 221 is connected to the high frequency input terminal 101 via the preamplifier 13, and the other end of the input-side coil 221 is connected to the ground. The output-side coil 222 is an example of a second output-side coil. One end of the output-side coil 222 is connected to the input end of the amplifier 11, and the other end of the output-side coil 222 is connected to the input end of the amplifier 12. The input-side coil 221 and the output-side coil 222 are electromagnetically coupled to each other. With the above configuration, the input transformer 22 converts a high frequency non-balanced signal outputted from the preamplifier 13 into two high frequency balanced signals having mutually opposite phases (power distribution).

The output transformer 21 includes an input-side coil 211 and an output-side coil 212.

The input-side coil 211 is an example of a first input-side coil. One end of the input-side coil 211 is connected to the output end of the amplifier 11, and the other end of the input-side coil 211 is connected to the output end of the amplifier 12. The output-side coil 212 is an example of a first output-side coil. One end of the output-side coil 212 is connected to the high frequency output terminal 102 via the capacitor 43, and the other end of the output-side coil 212 is connected to the ground. The input-side coil 211 and the output-side coil 212 are electromagnetically coupled to each other. According to the above configuration, the output transformer 21 combines the first high frequency balanced signal outputted from the amplifier 11 and the second high frequency balanced signal outputted from the amplifier 12 in power, and outputs a high frequency non-balanced signal.

The bypass capacitor 41 is an example of a first bypass capacitor. One end (one electrode) of the bypass capacitor 41 is connected to the midpoint of the input-side coil 211 and the Vcc terminal 103, and the other end (the other electrode) of the bypass capacitor 41 is connected to the ground. The bypass capacitor 41 has a capacitance value of 100 pF or more, for example, and has a function of suppressing the fundamental waves of the high frequency signals outputted from the amplifiers 11 and 12 from leaking into the power supply circuit. Note that the bypass capacitor 41 may also be loaded in the power supply circuit.

The bypass capacitor 42 is an example of a second bypass capacitor. One end (one electrode) of the bypass capacitor 42 is connected to the midpoint of the output-side coil 222 and the Vb terminal 104, and the other end (the other electrode) of the bypass capacitor 42 is connected to the ground. The bypass capacitor 42 has a capacitance value of 100 pF or more, for example, and has a function of suppressing the fundamental waves of the high frequency signals inputted to the amplifiers 11 and 12 from leaking into the bias circuit. Note that the bypass capacitor 42 may also be loaded in the bias circuit.

The bypass capacitors 41 and 42 have a function of reducing the impedance in a low frequency band (particularly in a low frequency band of 10 MHz or less).

The inductor 31 is an example of a first inductor. One end of the inductor 31 is connected to the output end of the amplifier 11 and one end of the input-side coil 211, and the other end of the inductor 31 is connected to the midpoint of the input-side coil 211. The inductor 32 is an example of a second inductor. One end of the inductor 32 is connected to the output end of the amplifier 12 and the other end of the input-side coil 211, and the other end of the inductor 32 is connected to the midpoint of the input-side coil 211.

Note that one end of the bypass capacitor 41, the Vcc terminal 103, the other end of the inductor 31, and the other end of the inductor 32 are not limited to being connected to the midpoint of the input-side coil 211, as long as they are connected to a node on the input-side coil 211 other than one end and the other end of the input-side coil 211.

The inductor 33 is an example of a third inductor. One end of the inductor 33 is connected to the input end of the amplifier 11 and one end of the output-side coil 222, and the other end of the inductor 33 is connected to the midpoint of the output-side coil 222. The inductor 34 is an example of a fourth inductor. One end of the inductor 34 is connected to the input end of the amplifier 12 and the other end of the output-side coil 222, and the other end of the inductor 34 is connected to the midpoint of the output-side coil 222.

Note that one end of the bypass capacitor 42, the Vb terminal 104, the other end of the inductor 33, and the other end of the inductor 34 are not limited to being connected to the midpoint of the output-side coil 222, as long as they are connected to a node on the output-side coil 222 other than one end and the other end of the output-side coil 222.

The capacitor 43 is an example of a matching circuit, and is arranged in series between one end of the output-side coil 212 and the high frequency output terminal 102. The capacitor 43 can suppress unnecessary signals among the signals outputted from one end of the output-side coil 212.

Note that, in the amplifier circuit 10 according to the present embodiment, the preamplifier 13, the input transformer 22, the bypass capacitor 42, the Vb terminal 104, the inductors 33 and 34, and the capacitor 43 are not essential components.

In the amplifier circuit 10 according to the present embodiment, the power supply voltage Vcc is supplied from the midpoint of the output transformer 21 to the output end of the amplifier 11 and the output end of the amplifier 12 by using the fact that the midpoint of the output transformer 21 is a virtual ground. Also, the bias voltage Vb is supplied from the midpoint of the input transformer 22 to the input end of the amplifier 11 and the input end of the amplifier 12 by using the fact that the midpoint of the input transformer 22 is a virtual ground.

### [1.3 Circuit Configurations of Amplifier Circuits According to Variations 1 and 2]

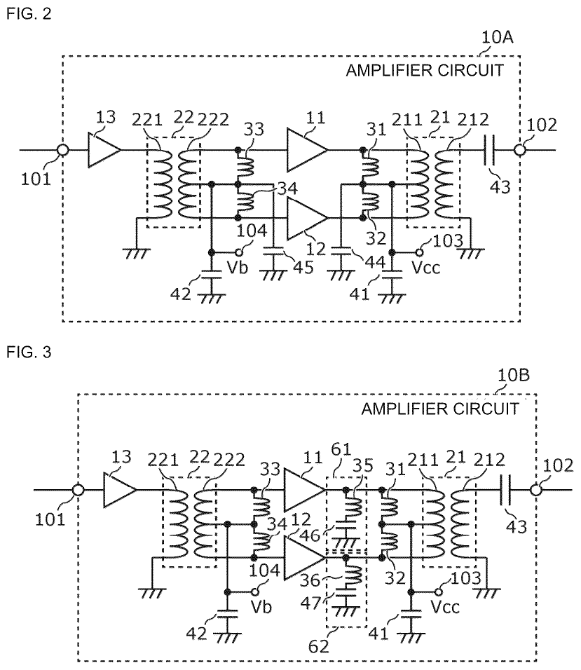

FIG. 2 is a circuit configuration diagram of an amplifier circuit 10A according to Variation 1. As shown in FIG. 2, the amplifier circuit 10A includes amplifiers 11 and 12, a preamplifier 13, an output transformer 21, an input transformer 22, bypass capacitors 41 and 42, capacitors 43, 44 and 45, inductors 31, 32, 33 and 34, a high frequency input terminal 101, a high frequency output terminal 102, a Vcc terminal 103, and a Vb terminal 104. The amplifier circuit 10A according to the present variation differs from the amplifier circuit 10 according to the embodiment in that the capacitors 44 and 45 are added. Hereinafter, the amplifier circuit 10A according to the present variation will be described with a focus on the differences from the amplifier circuit 10 according to the embodiment.

The capacitor 44 is an example of a first capacitor. One end (one electrode) of the capacitor 44 is connected to the other end of the inductor 31 and the other end of the inductor 32, and the other end (the other electrode) of the capacitor 44 is connected to the ground. That is, the capacitor 44 is connected between the other ends of the inductor 31 and inductor 32 and the ground.

The capacitor 45 is an example of a second capacitor. One end (one electrode) of the capacitor 45 is connected to the other end of the inductor 33 and the other end of the inductor 34, and the other end (the other electrode) of the capacitor 45 is connected to the ground. That is, the capacitor 45 is connected between the other ends of the inductor 33 and inductor 34 and the ground.

FIG. 3 is a circuit configuration diagram of an amplifier circuit 10B according to Variation 2. As shown in FIG. 3, the amplifier circuit 10B includes amplifiers 11 and 12, a preamplifier 13, an output transformer 21, an input transformer 22, bypass capacitors 41 and 42, capacitors 43, 46 and 47, inductors 31, 32, 33, 34, 35 and 36, a high frequency input terminal 101, a high frequency output terminal 102, a Vcc terminal 103, and a Vb terminal 104. The amplifier circuit 10B according to the present variation differs from the amplifier circuit 10 according to the embodiment in that the capacitors 46 and 47 and the inductors 35 and 36 are added. Hereinafter, the amplifier circuit 10B according to the present variation will be described with a focus on the differences from the amplifier circuit 10 according to the embodiment.

The capacitor 46 and the inductor 35 are connected in series to each other to constitute an LC series resonance circuit 61 (first LC series circuit). The series connection circuit of the capacitor 46 and the inductor 35 is connected between the output end of the amplifier 11 and the ground. With the above configuration, the series connection circuit of the capacitor 46 and the inductor 35 has a function of suppressing harmonic waves outputted from the amplifier 11. In the present variation, the inductor 35 is connected to the output end of the amplifier 11 and the capacitor 46 is connected to the ground, but the capacitor 46 may be connected to the output end of the amplifier 11 and the inductor 35 may be connected to the ground.

The capacitor 47 and the inductor 36 are connected in series to each other to constitute an LC series resonance circuit 62 (second LC series circuit). The series connection circuit of the capacitor 47 and the inductor 36 is connected between the output end of the amplifier 12 and the ground. With the above configuration, the series connection circuit of the capacitor 47 and the inductor 36 has a function of suppressing harmonic waves outputted from the amplifier 12. In the present variation, the inductor 36 is connected to the output end of the amplifier 12 and the capacitor 47 is connected to the ground, but the capacitor 47 may be connected to the output end of the amplifier 12 and the inductor 36 may be connected to the ground.

With the configuration of the amplifier circuit 10B according to Variation 2, since high-order harmonic components can be short-circuited by the first LC series circuit and the second LC series circuit, particularly second-order harmonic components can be suppressed.

### [1.4 Amplifier Circuit According to Comparative Example]

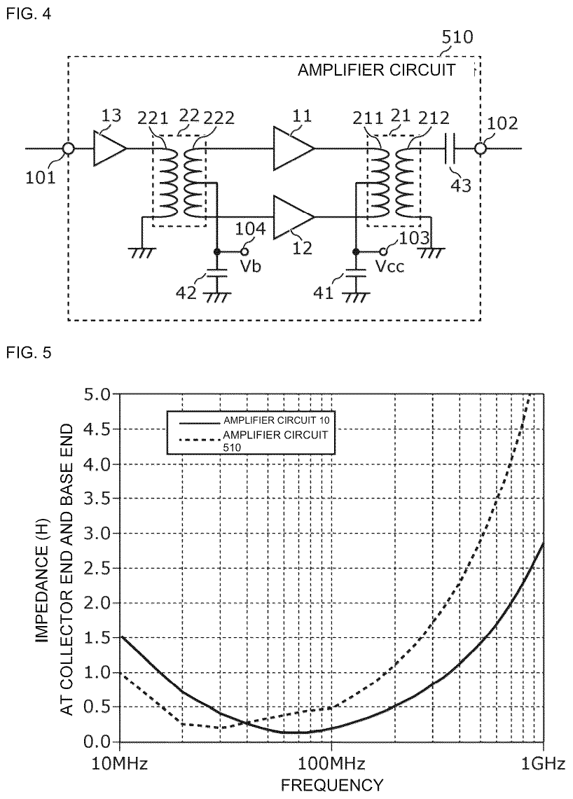

FIG. 4 is a circuit configuration diagram of an amplifier circuit 510 according to a comparative example. As shown in FIG. 4, the amplifier circuit 510 according to the comparative example includes amplifiers 11 and 12, a preamplifier 13, an output transformer 21, an input transformer 22, bypass capacitors 41 and 42, a capacitor 43, a high frequency input terminal 101, a high frequency output terminal 102, a Vcc terminal 103, and a Vb terminal 104. The amplifier circuit 510 according to the comparative example differs from the amplifier circuit 10 according to the embodiment only in that the inductors 31 to 34 are not added.

In the amplifier circuit 510 according to the comparative example, the power supply voltage Vcc is supplied from the midpoint of the output transformer 21 to the output end of the amplifier 11 and the output end of the amplifier 12 by using the fact that the midpoint of the output transformer 21 is a virtual ground. Also, the bias voltage Vb is supplied from the midpoint of the input transformer 22 to the input end of the amplifier 11 and the input end of the amplifier 12 by using the fact that the midpoint of the input transformer 22 is a virtual ground.

However, in the amplifier circuit 510, since the path for supplying the power supply voltage Vcc from the bypass capacitor 41 to the output end of the amplifier 11 and the path for supplying the bias voltage Vb from the bypass capacitor 41 to the output end of the amplifier 12 include the inductance component of the input-side coil 211, the impedance in a low frequency band such as 100 MHz, which is the baseband bandwidth of the NR signal, increases. Thus, there is a problem that the intermodulation distortion component generated by mixing the baseband with the fundamental wave band of the high frequency signal increases (i.e., so-called memory effect becomes significant), so that the ACLR of the high frequency signal in the fundamental wave band deteriorates.

Even assuming the LC series resonance circuit disclosed in Patent Document 2 is added to the amplifier circuit 510 according to the comparative example, the LC series resonance circuit is a circuit for suppressing high-order harmonic waves. Therefore, the impedance in the low frequency band of the path for supplying the power supply voltage Vcc from the bypass capacitor 41 to the output end of the amplifier 11 and the path for supplying the bias voltage Vb from the bypass capacitor 41 to the output end of the amplifier 12 does not decrease, which also causes the memory effect to become significant, so that the ACLR of the high frequency signal in the fundamental wave band deteriorates.

### [1.5 Comparison of Characteristics of Amplifier Circuits According to Embodiment and Comparative Example]

FIG. 5 is a graph showing frequency characteristics of the impedances of the amplifier circuits according to the embodiment and the comparative example. Specifically, FIG. 5 shows the impedance at the input ends (base ends) of the amplifiers 11 and 12 and the output ends (collector ends) of the amplifiers 11 and 12.

In the amplifier circuit 10 according to the embodiment, the impedance in the vicinity of 100 MHZ (to 200 MHz), which is the baseband bandwidth of the NR signal, is reduced by almost half as compared with the amplifier circuit 510 according to the comparative example. This is because, in the amplifier circuit 10, the inductor 31 is connected in parallel between one end and the midpoint of the input-side coil 211, so that the inductance component of the path for supplying the power supply voltage Vcc from the bypass capacitor 41 to the output end of the amplifier 11 is reduced. In addition, this is because, in the amplifier circuit 10, the inductor 32 is connected in parallel between the other end and the midpoint of the input-side coil 211, so that the inductance component of the path for supplying the power supply voltage Vcc from the bypass capacitor 41 to the output end of the amplifier 12 is reduced.

In addition, this is because, in the amplifier circuit 10, the inductor 33 is connected in parallel between one end and the midpoint of the output-side coil 222, so that the inductance component of the path for supplying the bias voltage Vb from the bypass capacitor 42 to the input end of the amplifier 11 is reduced. In addition, this is because, in the amplifier circuit 10, the inductor 34 is connected in parallel between the other end and the midpoint of the output-side coil 222, so that the inductance component of the path for supplying the bias voltage Vb from the bypass capacitor 42 to the input end of the amplifier 12 is reduced.

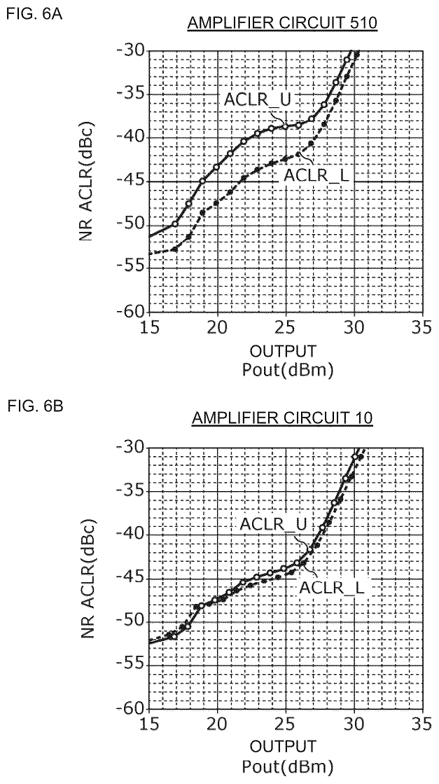

FIG. 6A is a graph showing the ACLR of the amplifier circuit 510 according to the comparative example. FIG. 6B is a graph showing the ACLR of the amplifier circuit 10 according to the embodiment. FIGS. 6A and 6B show the output power dependence of the ACLR of the NR signal near the high frequency side (denoted as ACLR_U) and the output power dependence of the ACLR of the NR signal near the low frequency side (denoted as ACLR_L).

In the amplifier circuit 510 according to the comparative example, the ACLR_U is deteriorated relative to the ACLR_L. In contrast, in the amplifier circuit 10 according to the embodiment, the ACLR_U is particularly improved, and the asymmetrical characteristics of the ACLR_L and ACLR_U are suppressed to ensure symmetry. That is, in the amplifier circuit 10 according to the embodiment, by arranging the inductors 31 to 34, the memory effect is suppressed by reducing the impedance in the low frequency band (baseband) without increasing the number of bypass capacitors, so that the ACLR is improved.

In the amplifier circuit 10A according to Variation 1, the impedance in the low frequency band (baseband) can be further reduced by, in addition to the inductors 31 to 34, grounding the midpoint of the input-side coil 211 in a more high-frequency manner by the capacitor 44, so that the memory effect can be further suppressed.

### [1.6 Voltage Combining Type Doherty Amplifier Circuit According to Variation 3]

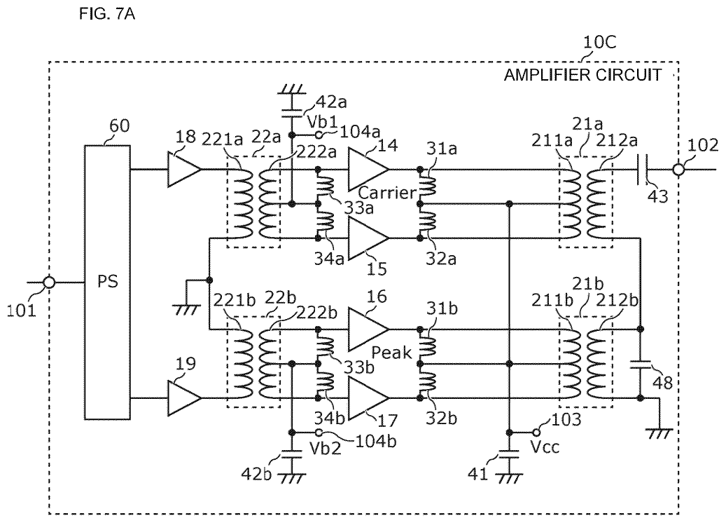

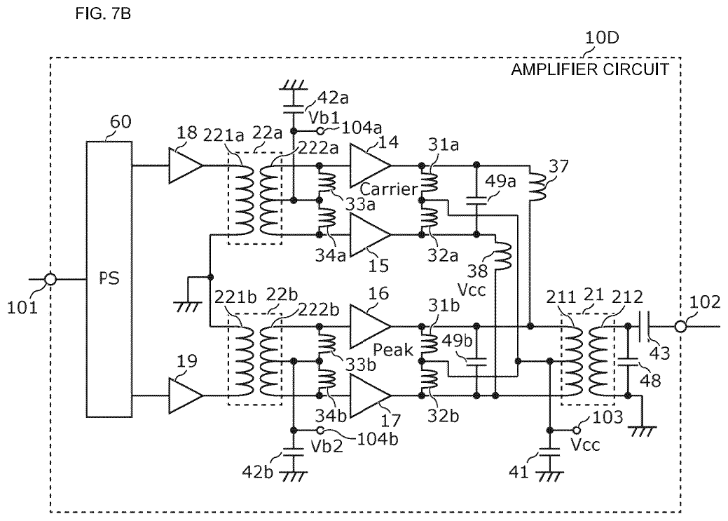

FIG. 7A is a circuit configuration diagram of an amplifier circuit 10C according to Variation 3. The amplifier circuit 10C includes carrier amplifiers 14 and 15, peak amplifiers 16 and 17, preamplifiers 18 and 19, output transformers 21a and 21b, input transformers 22a and 22b, bypass capacitors 41, 42a and 42b, capacitors 43 and 48, inductors 31a, 31b, 32a, 32b, 33a, 33b, 34a and 34b, a phase shift circuit 60, a high frequency input terminal 101, a high frequency output terminal 102, a Vcc terminal 103, and Vb terminals 104a and 104b. The amplifier circuit 10C according to the present variation is a Doherty amplifier circuit having the carrier amplifiers 14 and 15 and the peak amplifiers 16 and 17. The amplifier circuit 10C according to the present variation differs from the amplifier circuit 10 according to the embodiment in that the carrier amplifiers 14 and 15 constitute a differential amplification type amplifier and the peak amplifiers 16 and 17 constitute a differential amplification type amplifier. Hereinafter, the amplifier circuit 10C according to the present variation will be described with a focus on the differences from the amplifier circuit 10 according to the embodiment.

A Doherty amplifier circuit means an amplifier circuit that achieves high efficiency by using a plurality of amplifying elements as carrier amplifiers and peak amplifiers. A carrier amplifier means an amplifying element that operates in a Doherty amplifier circuit regardless of whether the power of the high frequency signal (input) is low or high. A peak amplifier means an amplifying element that mainly operates in a Doherty amplifier circuit assuming the power of the high frequency signal (input) is high. Therefore, assuming the input power of the high frequency signal is low, the high frequency signal is amplified mainly by the carrier amplifier, and assuming the input power of the high frequency signal is high, the high frequency signal is amplified and combined by the carrier amplifier and the peak amplifier. Due to such operation, in the Doherty amplifier circuit, the load impedance at low output power is increased assuming seen from the carrier amplifier, so that the efficiency at low output power is improved.

The Vcc terminal 103 is an example of the power supply voltage supply terminal, and is connected to a power supply circuit (not shown) that outputs the power supply voltage Vcc. The Vb terminal 104a is an example of the bias voltage supply terminal, and is connected to a bias circuit (not shown) that outputs a bias voltage Vb1 supplied to the carrier amplifiers 14 and 15. The Vb terminal 104b is an example of the bias voltage supply terminal, and is connected to a bias circuit (not shown) that outputs a bias voltage Vb2 supplied to the peak amplifiers 16 and 17.

The preamplifiers 18 and 19 amplify the transmission signal(s) of the band A and/or band B inputted from the high frequency input terminal 101 via the phase shift circuit 60.

The phase shift circuit 60 distributes a signal RF0 outputted from the RFIC 3, and outputs distributed signals RF1 and RF2 to the preamplifiers 18 and 19, respectively. At this time, the phase shift circuit 60 adjusts the phases of the signals RF1 and RF2. For example, the phase shift circuit 60 shifts the signal RF2 by (−90+α)° with respect to the signal RF1.

The configuration of the phase shift circuit 60 and the preamplifiers 18 and 19 is not limited to the configuration described above. For example, the preamplifiers 18 and 19 may be disposed as one preamplifier in the preceding stage of the phase shift circuit 60. Also, the amplifier circuit 10C does not necessarily include the phase shift circuit 60 and the preamplifiers 18 and 19.

Each of the carrier amplifiers 14 and 15 and the peak amplifiers 16 and 17 has an amplification transistor. The amplification transistor is, for example, a bipolar transistor such as an HBT or a field effect transistor such as a MOSFET.

The carrier amplifier 14 is an example of a third amplifying element, and amplifies a transmission signal of the band A or band B inputted to the carrier amplifier 14. The carrier amplifier 14 is, for example, a class A (or class AB) amplifier circuit capable of performing amplification operation for all power levels of the signal inputted to the carrier amplifier 14, and can perform highly efficient amplification operation, particularly in a low output region and a medium output region. The carrier amplifier 14 amplifies a high frequency balanced signal outputted from one end of the output-side coil 222a, and outputs a third high frequency balanced signal.

The carrier amplifier 15 is an example of a fourth amplifying element, and amplifies a transmission signal of the band A or band B inputted to the carrier amplifier 15. The carrier amplifier 15 is, for example, a class A (or class AB) amplifier circuit capable of performing amplification operation for all power levels of the signal inputted to the carrier amplifier 15, and can perform highly efficient amplification operation, particularly in a low output region and a medium output region. The carrier amplifier 15 amplifies a high frequency balanced signal outputted from the other end of the output-side coil 222a, and outputs a fourth high frequency balanced signal.

The peak amplifier 16 is an example of the first amplifying element, and amplifies a transmission signal of the band A or band B inputted to the peak amplifier 16. The peak amplifier 16 is, for example, a class C amplifier circuit capable of performing amplification operation in a region where the power level of the signal inputted to the peak amplifier 16 is high. The peak amplifier 16 amplifies a high frequency balanced signal outputted from one end of the output-side coil 222b, and outputs a first high frequency balanced signal.

The peak amplifier 17 is an example of the second amplifying element, and amplifies a transmission signal of the band A or band B inputted to the peak amplifier 17. The peak amplifier 17 is, for example, a class C amplifier circuit capable of performing amplification operation in a region where the power level of a signal inputted to the peak amplifier 17 is high. The peak amplifier 17 amplifies a high frequency balanced signal outputted from the other end of the output-side coil 222b, and outputs a second high frequency balanced signal.

A bias current smaller than the bias current applied to the amplification transistors of the carrier amplifiers 14 and 15 may be applied to the amplification transistors of the peak amplifiers 16 and 17. Thus, the higher the power level of the signals inputted to the peak amplifiers 16 and 17, the lower the output impedance becomes. Thus, the peak amplifiers 16 and 17 can perform an amplification operation with low distortion in a high output region.

The input transformer 22a is an example of a second input transformer, and includes an input-side coil 221a and an output-side coil 222a.

The input-side coil 221a is an example of a third input-side coil. One end of the input-side coil 221a is connected to the high frequency input terminal 101 via the preamplifier 18 and the phase shift circuit 60, and the other end of the input-side coil 221a is connected to the ground. The output-side coil 222a is an example of a third output-side coil. One end of the output-side coil 222a is connected to the input end of the carrier amplifier 14, and the other end of the output-side coil 222a is connected to the input end of the carrier amplifier 15. The input-side coil 221a and the output-side coil 222a are electromagnetically coupled to each other. With the above configuration, the input transformer 22a converts the high frequency non-balanced signal outputted from the preamplifier 18 into two high frequency balanced signals having mutually opposite phases (power distribution).

The input transformer 22b is an example of the first input transformer, and includes an input-side coil 221b and an output-side coil 222b.

The input-side coil 221b is an example of the second input-side coil. One end of the input-side coil 221b is connected to the high frequency input terminal 101 via the preamplifier 19 and the phase shift circuit 60, and the other end of the input-side coil 221b is connected to the ground. The output-side coil 222b is an example of the second output-side coil. One end of the output-side coil 222b is connected to the input end of the peak amplifier 16, and the other end of the output-side coil 222b is connected to the input end of the peak amplifier 17. The input-side coil 221b and the output-side coil 222b are electromagnetically coupled to each other. With the above configuration, the input transformer 22b converts the high frequency non-balanced signal outputted from the preamplifier 19 into two high frequency balanced signals having mutually opposite phases (power distribution).

The output transformer 21a includes an input-side coil 211a and an output-side coil 212a.

The input-side coil 211a has one end thereof connected to the output end of the carrier amplifier 14, and the other end thereof connected to the output end of the carrier amplifier 15. The output-side coil 212a has one end thereof connected to the high frequency output terminal 102 via the capacitor 43, and the other end thereof connected to one end of the output-side coil 212b. The input-side coil 211a and the output-side coil 212a are electromagnetically coupled to each other. With the above configuration, the output transformer 21a combines the third high frequency balanced signal outputted from the carrier amplifier 14 and the fourth high frequency balanced signal outputted from the carrier amplifier 15 in power, and outputs a high frequency non-balanced signal.

The output transformer 21b includes an input-side coil 211b and an output-side coil 212b.

The input-side coil 211b is an example of the first input-side coil. One end of the input-side coil 211b is connected to the output end of the peak amplifier 16, and the other end of the input-side coil 211b is connected to the output end of the peak amplifier 17. The output-side coil 212b is an example of the first output-side coil. One end of the output-side coil 212b is connected to the other end of the output-side coil 212a, and the other end of the output-side coil 212b is connected to the ground. The capacitor 48 is connected between both ends of the output-side coil 212b. The input-side coil 211b and the output-side coil 212b are electromagnetically coupled to each other. With the above configuration, the output transformer 21b combines the first high frequency balanced signal outputted from the peak amplifier 16 and the second high frequency balanced signal outputted from the peak amplifier 17 in power, and outputs a high frequency non-balanced signal.

The high frequency non-balanced signal obtained by combining the signals outputted from the carrier amplifiers 14 and 15 in power and the high frequency non-balanced signal obtained by combining the signals outputted from the peak amplifiers 16 and 17 in power are combined in voltage by the output transformers 21a and 21b, and the high frequency signal combined in voltage is outputted from the high frequency output terminal 102 via the capacitor 43.

The bypass capacitor 41 is an example of the first bypass capacitor. One end (one electrode) of the bypass capacitor 41 is connected to the midpoint of the input-side coil 211a, the midpoint of the input-side coil 211b, and the Vcc terminal 103, and the other end (the other electrode) of the bypass capacitor 41 is connected to the ground. The bypass capacitor 41 has a function of suppressing the fundamental waves of the high frequency signals outputted from the carrier amplifiers 14 and 15 and the fundamental waves of the high frequency signals outputted from the peak amplifiers 16 and 17 from leaking into the power supply circuit.

The bypass capacitor 42a is an example of a third bypass capacitor. One end (one electrode) of the bypass capacitor 42a is connected to the midpoint of the output-side coil 222a and the Vb terminal 104a, and the other end (the other electrode) of the bypass capacitor 42a is connected to the ground. The bypass capacitor 42a has a function of suppressing the fundamental waves of the high frequency signals inputted to the carrier amplifiers 14 and 15 from leaking into the bias circuit.

The bypass capacitor 42b is an example of the second bypass capacitor. One end (one electrode) of the bypass capacitor 42b is connected to the midpoint of the output-side coil 222b and the Vb terminal 104b, and the other end (the other electrode) of the bypass capacitor 42b is connected to the ground. The bypass capacitor 42b has a function of suppressing the fundamental waves of the high frequency signals inputted to the peak amplifiers 16 and 17 from leaking into the bias circuit.

In addition, the bypass capacitors 41, 42a and 42b have a function of reducing the impedance in a low frequency band (particularly at a frequency of 10 MHz or lower).

The inductor 31a is an example of a fifth inductor. One end of the inductor 31a is connected to the output end of the carrier amplifier 14 and one end of the input-side coil 211a, and the other end of the inductor 31a is connected to the midpoint of the input-side coil 211a. The inductor 32a is an example of a sixth inductor. One end of the inductor 32a is connected to the output end of the carrier amplifier 15 and the other end of the input-side coil 211a, and the other end of the inductor 32a is connected to the midpoint of the input-side coil 211a.

The inductor 31b is an example of the first inductor. One end of the inductor 31b is connected to the output end of the peak amplifier 16 and one end of the input-side coil 211b, and the other end of the inductor 31b is connected to the midpoint of the input-side coil 211b. The inductor 32b is an example of the second inductor. One end of the inductor 32b is connected to the output end of the peak amplifier 17 and the other end of the input-side coil 211b, and the other end of the inductor 32b is connected to the midpoint of the input-side coil 211b.

Note that one end of the bypass capacitor 41, the Vcc terminal 103, the other end of the inductor 31a, and the other end of the inductor 32a are not limited to being connected to the midpoint of the input-side coil 211a, as long as they are connected to a node on the input-side coil 211a other than one end and the other end of the input-side coil 211a. Also, one end of the bypass capacitor 41, the Vcc terminal 103, the other end of the inductor 31b, and the other end of the inductor 32b are not limited to being connected to the midpoint of the input-side coil 211b, as long as they are connected to a node on the input-side coil 211b other than one end and the other end of the input-side coil 211b.

The inductor 33a is an example of a seventh inductor. One end of the inductor 33a is connected to the input end of the carrier amplifier 14 and one end of the output-side coil 222a, and the other end of the inductor 33a is connected to the midpoint of the output-side coil 222a. The inductor 34a is an example of an eighth inductor. One end of the inductor 34a is connected to the input end of the carrier amplifier 15 and the other end of the output-side coil 222a, and the other end of the inductor 34a is connected to the midpoint of the output-side coil 222a.

The inductor 33b is an example of the third inductor. One end of the inductor 33b is connected to the input end of the peak amplifier 16 and one end of the output-side coil 222b, and the other end of the inductor 33b is connected to the midpoint of the output-side coil 222b. The inductor 34b is an example of the fourth inductor. One end of the inductor 34b is connected to the input end of the peak amplifier 17 and the other end of the output-side coil 222b, and the other end of the inductor 34b is connected to the midpoint of the output-side coil 222b.

Note that one end of the bypass capacitor 42a, the Vb terminal 104a, the other end of the inductor 33a, and the other end of the inductor 34a are not limited to being connected to the midpoint of the output-side coil 222a, as long as they are connected to a node on the output-side coil 222a other than one end and the other end of the output-side coil 222a. Also, one end of the bypass capacitor 42b, the Vb terminal 104b, the other end of the inductor 33b, and the other end of the inductor 34b are not limited to being connected to the midpoint of the output-side coil 222b, as long as they are connected to a node on the output-side coil 222b other than one end and the other end of the output-side coil 222b.

Note that, in the amplifier circuit 10C according to the present variation, the preamplifiers 18 and 19, the input transformers 22a and 22b, the bypass capacitors 42a and 42b, the Vb terminals 104a and 104b, the inductors 33a, 33b, 34a and 34b, and the capacitor 43 are not essential components.

In the amplifier circuit 10C according to the present variation, the power supply voltage Vcc is supplied from the midpoint of the output transformer 21a and the midpoint of the output transformer 21b to the output ends of the carrier amplifiers 14 and 15 and the peak amplifiers 16 and 17 by using the fact that the midpoint of the output transformer 21a and the midpoint of the output transformer 21b are virtual grounds. Further, the bias voltage Vb1 is supplied from the midpoint of the input transformer 22a to the input ends of the carrier amplifiers 14 and 15 by using the fact that the midpoint of the input transformer 22a is a virtual ground. Further, the bias voltage Vb2 is supplied from the midpoint of the input transformer 22b to the input ends of the peak amplifiers 16 and 17 by using the fact that the midpoint of the input transformer 22b is a virtual ground.

With the above configuration, since the inductor 31a is connected in parallel between one end and the midpoint of the input-side coil 211a, the inductance component of the path for supplying the power supply voltage Vcc from the bypass capacitor 41 to the output end of the carrier amplifier 14 is reduced. In addition, since the inductor 32a is connected in parallel between the other end and the midpoint of the input-side coil 211a, the inductance component of the path for supplying the power supply voltage Vcc from the bypass capacitor 41 to the output end of the carrier amplifier 15 is reduced. Therefore, the output impedances of the carrier amplifiers 14 and 15 in a low frequency band such as the baseband can be reduced. In addition, since the inductor 31b is connected in parallel between one end and the midpoint of the input-side coil 211b, the inductance component of the path for supplying the power supply voltage Vcc from the bypass capacitor 41 to the output end of the peak amplifier 16 is reduced. In addition, since the inductor 32b is connected in parallel between the other end and the midpoint of the input-side coil 211b, the inductance component of the path for supplying the power supply voltage Vcc from the bypass capacitor 41 to the output end of the peak amplifier 17 is reduced. Therefore, the output impedances of the peak amplifiers 16 and 17 in a low frequency band such as the baseband can be reduced.

Further, since the inductor 33a is connected in parallel between one end and the midpoint of the output-side coil 222a, the inductance component of the path for supplying the bias voltage Vb1 from the bypass capacitor 42a to the input end of the carrier amplifier 14 is reduced. Also, since the inductor 34a is connected in parallel between the other end and the midpoint of the output-side coil 222a, the inductance component of the path for supplying the bias voltage Vb1 from the bypass capacitor 42a to the input end of the carrier amplifier 15 is reduced. Therefore, the input impedances of the carrier amplifiers 14 and 15 in a low frequency band such as the baseband can be reduced. Also, since the inductor 33b is connected in parallel between one end and the midpoint of the output-side coil 222b, the inductance component of the path for supplying the bias voltage Vb2 from the bypass capacitor 42b to the input end of the peak amplifier 16 is reduced. Also, since the inductor 34b is connected in parallel between the other end and the midpoint of the output-side coil 222b, the inductance component of the path for supplying the bias voltage Vb2 from the bypass capacitor 42b to the input end of the peak amplifier 17 is reduced. Therefore, the input impedances of the peak amplifiers 16 and 17 in a low frequency band such as the baseband can be reduced.

Thus, for example, the intermodulation distortion component generated by mixing the baseband with the fundamental wave band of the high frequency signal can be suppressed, so that the deterioration of the ACLR of the high frequency signal in the fundamental wave band can be suppressed.

### [1.7 Current Combining Type Doherty Amplifier Circuit According to Variation 4]

FIG. 7B is a circuit configuration diagram of an amplifier circuit 10D according to Variation 4. The amplifier circuit 10D includes carrier amplifiers 14 and 15, peak amplifiers 16 and 17, preamplifiers 18 and 19, an output transformer 21, input transformers 22a and 22b, bypass capacitors 41, 42a and 42b, capacitors 43, 48, 49a and 49b, inductors 31a, 31b, 32a, 32b, 33a, 33b, 34a, 34b, 37 and 38, a phase shift circuit 60, a high frequency input terminal 101, a high frequency output terminal 102, a Vcc terminal 103, and Vb terminals 104a and 104b. The amplifier circuit 10D according to the present variation differs from the amplifier circuit 10C according to Variation 3 in that the amplifier circuit 10D is a voltage combining type Doherty amplifier circuit, while the amplifier circuit 10C is a current combining type Doherty amplifier circuit. The amplifier circuit 10D according to the present variation will be described with a focus on the differences from the amplifier circuit 10C according to Variation 3.

The output transformer 21 includes an input-side coil 211 and an output-side coil 212. One end of the input-side coil 211 is connected to the output end of the carrier amplifier 14 via the inductor 37, and is connected to the output end of the peak amplifier 16. The other end of the input-side coil 211 is connected to the output end of the carrier amplifier 15 via the inductor 38, and is connected to the output end of the peak amplifier 17. One end of the output-side coil 212 is connected to the high frequency output terminal 102 via the capacitor 43, and the other end of the output-side coil 212 is connected to the ground. The input-side coil 211 and the output-side coil 212 are electromagnetically coupled to each other.

With the above configuration, a third high frequency balanced signal outputted from the carrier amplifier 14 and a first high frequency balanced signal outputted from the peak amplifier 16 are combined in current at one end of the input-side coil 211, and a fourth high frequency balanced signal outputted from the carrier amplifier 15 and a second high frequency balanced signal outputted from the peak amplifier 17 are combined in current at the other end of the input-side coil 211. The two high frequency balanced signals combined in current are combined in power by the output transformer 21 and outputted as a high frequency non-balanced signal from the high frequency output terminal 102.

Note that it is sufficient that the inductors 37 and 38 are circuits for shifting the phase of signals; for example, the inductors 37 and 38 may be phase shifting lines.

The bypass capacitor 41 is an example of the first bypass capacitor, and one end (one electrode) of the bypass capacitor 41 is connected to the midpoint of the input-side coil 211 and the Vcc terminal 103, and the other end (the other electrode) of the bypass capacitor 41 is connected to the ground. The bypass capacitor 41 has a function of suppressing the fundamental waves of the high frequency signals outputted from the carrier amplifiers 14 and 15 and the fundamental waves of the high frequency signals outputted from the peak amplifiers 16 and 17 from leaking into the power supply circuit.

The inductor 31a is an example of the fifth inductor. One end of the inductor 31a is connected to the output end of the carrier amplifier 14 and is connected to one end of the input-side coil 211 via the inductor 37, and the other end of the inductor 31a is connected to the midpoint of the input-side coil 211. The inductor 32a is an example of the sixth inductor. One end of the inductor 32a is connected to the output end of the carrier amplifier 15 and is connected to the other end of the input-side coil 211 via the inductor 38, and the other end of the inductor 32a is connected to the midpoint of the input-side coil 211.

The inductor 31b is an example of the first inductor. One end of the inductor 31b is connected to the output end of the peak amplifier 16 and one end of the input-side coil 211, and the other end of the inductor 31b is connected to the midpoint of the input-side coil 211. The inductor 32b is an example of the second inductor. One end of the inductor 32b is connected to the output end of the peak amplifier 17 and the other end of the input-side coil 211, and the other end of the inductor 32b is connected to the midpoint of the input-side coil 211.

Note that one end of the bypass capacitor 41, the Vcc terminal 103, the other end of the inductor 31a, and the other end of the inductor 32a are not limited to being connected to the midpoint of the input-side coil 211, as long as they are connected to a node on the input-side coil 211 other than one end and the other end of the input-side coil 211. Also, one end of the bypass capacitor 41, the Vcc terminal 103, the other end of the inductor 31b, and the other end of the inductor 32b are not limited to being connected to the midpoint of the input-side coil 211, as long as they are connected to a node on the input-side coil 211 other than one end and the other end of the input-side coil 211.

In the amplifier circuit 10D according to the present variation, the preamplifiers 18 and 19, the input transformers 22a and 22b, the bypass capacitors 42a and 42b, the Vb terminals 104a and 104b, the inductors 33a, 33b, 34a and 34b, and the capacitor 43 are not essential components.

In the amplifier circuit 10D according to the present variation, the power supply voltage Vcc is supplied from the midpoint of the output transformer 21 to the output ends of the carrier amplifiers 14 and 15 and the peak amplifiers 16 and 17 by using the fact that the midpoint of the output transformer 21 is a virtual ground. Further, the bias voltage Vb1 is supplied from the midpoint of the input transformer 22a to the input ends of the carrier amplifiers 14 and 15 by using the fact that the midpoint of the input transformer 22a is a virtual ground. Further, the bias voltage Vb2 is supplied from the midpoint of the input transformer 22b to the input ends of the peak amplifiers 16 and 17 by using the fact that the midpoint of the input transformer 22b is a virtual ground.

With the above configuration, since the inductor 31a is connected in parallel between one end and the midpoint of the input-side coil 211, the inductance component of the path for supplying the power supply voltage Vcc from the bypass capacitor 41 to the output end of the carrier amplifier 14 is reduced. In addition, since the inductor 32a is connected in parallel between the other end and the midpoint of the input-side coil 211, the inductance component of the path for supplying the power supply voltage Vcc from the bypass capacitor 41 to the output end of the carrier amplifier 15 is reduced. Therefore, the output impedances of the carrier amplifiers 14 and 15 in a low frequency band such as the baseband can be reduced. In addition, since the inductor 31b is connected in parallel between one end and the midpoint of the input-side coil 211, the inductance component of the path for supplying the power supply voltage Vcc from the bypass capacitor 41 to the output end of the peak amplifier 16 is reduced. In addition, since the inductor 32b is connected in parallel between the other end and the midpoint of the input-side coil 211, the inductance component of the path for supplying the power supply voltage Vcc from the bypass capacitor 41 to the output end of the peak amplifier 17 is reduced. Therefore, the output impedances of the peak amplifiers 16 and 17 in a low frequency band such as the baseband can be reduced.

Further, since the inductor 33a is connected in parallel between one end and the midpoint of the output-side coil 222a, the inductance component of the path for supplying the bias voltage Vb1 from the bypass capacitor 42a to the input end of the carrier amplifier 14 is reduced. Also, since the inductor 34a is connected in parallel between the other end and the midpoint of the output-side coil 222a, the inductance component of the path for supplying the bias voltage Vb1 from the bypass capacitor 42a to the input end of the carrier amplifier 15 is reduced. Therefore, the input impedances of the carrier amplifiers 14 and 15 in a low frequency band such as the baseband can be reduced. Also, since the inductor 33b is connected in parallel between one end and the midpoint of the output-side coil 222b, the inductance component of the path for supplying the bias voltage Vb2 from the bypass capacitor 42b to the input end of the peak amplifier 16 is reduced. Also, since the inductor 34b is connected in parallel between the other end and the midpoint of the output-side coil 222b, the inductance component of the path for supplying the bias voltage Vb2 from the bypass capacitor 42b to the input end of the peak amplifier 17 is reduced. Therefore, the input impedances of the peak amplifiers 16 and 17 in a low frequency band such as the baseband can be reduced.

Thus, for example, the intermodulation distortion component generated by mixing the baseband with the fundamental wave band of the high frequency signal can be suppressed, so that the deterioration of the ACLR of the high frequency signal in the fundamental wave band can be suppressed.

### [2. Arrangement of Components of Amplifier Circuit]

Next, the arrangement of the components of the amplifier circuit 10 according to the embodiment will be described.

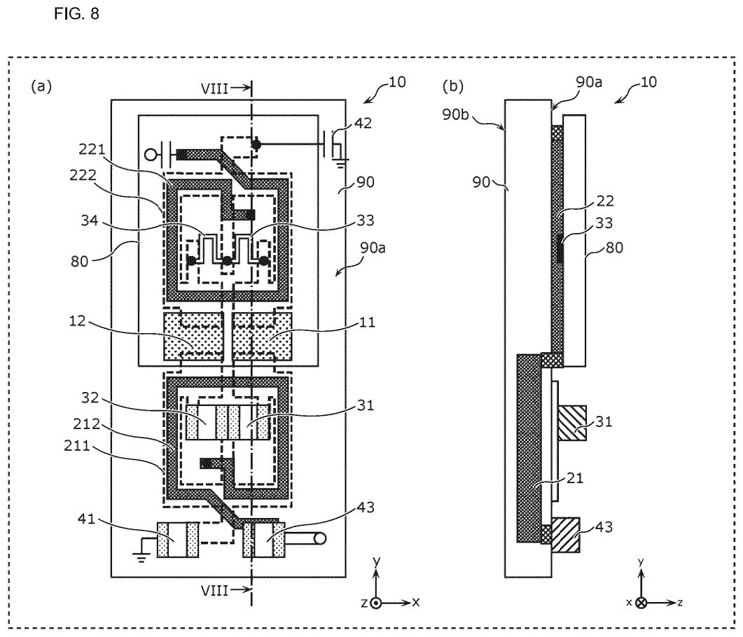

FIG. 8 is a plan view and a sectional view of the amplifier circuit 10 according to the embodiment. (a) of FIG. 8 shows the arrangement of the circuit components assuming a main surface 90a of a substrate 90 is viewed in a transparent manner from the positive direction side of a z-axis. (b) of FIG. 8 is a sectional view taken along line VIII-VIII in (a) of FIG. 8. Note that, in FIG. 8, some of the wires connecting the substrate 90 and each circuit component are omitted. The amplifier circuit 10 shown in FIG. 8 may further include a resin member covering the surface of the substrate 90 and a part of the circuit components, and a shield electrode layer covering the surface of the resin member; however, the resin member and the shield electrode layer are not shown in FIG. 8.

In addition to the circuit configuration shown in FIG. 1, the amplifier circuit 10 further includes the substrate 90.

The substrate 90 has main surfaces 90a and 90b facing each other, and is a substrate on which the circuit components constituting the amplifier circuit 10 are mounted. For example, a substrate having a multilayer structure formed by stacking a plurality of dielectric layers, a printed circuit board or the like can be used as the substrate 90. Examples of the substrate having a multilayer structure formed by stacking a plurality of dielectric layers include an LTCC (Low Temperature Co-fired Ceramics) substrate, an HTCC (High Temperature Co-fired Ceramics) substrate, a substrate with built-in components, and a substrate having an RDL (Redistribution Layer).

As shown in FIG. 8, the amplifiers 11 and 12, the input transformer 22, the inductors 31 to 34, the bypass capacitor 41, and the capacitor 43 are disposed on the main surface 90a of the substrate 90. The output transformer 21 is formed inside the substrate 90.

The amplifiers 11 and 12 are included in a semiconductor IC 80 disposed on the main surface 90a. The semiconductor IC 80 may be composed by using, for example, CMOS (Complementary Metal Oxide Semiconductor), and more specifically, may be manufactured by an SOI (Silicon on Insulator) process. The semiconductor IC may be composed of at least one of GaAs, SiGe, and GaN. Note that the semiconductor material of the semiconductor IC 80 is not limited to the above-described materials.

The input-side coil 211 and the output-side coil 212 constituting the output transformer 21 are composed of planar conductors formed inside the substrate 90. Assuming the main surface 90a is viewed in plan view, the input-side coil 211 and the output-side coil 212 at least partially overlap with each other. Note that the input-side coil 211 and the output-side coil 212 may at least partially be formed at least on the main surface 90a or inside the substrate 90.

The inductors 31 and 32 are surface-mounted components, and are disposed on the main surface 90a.

Assuming the main surface 90a is viewed in plan view, the inductors 31 and 32 are disposed in a region surrounded by the output transformer 21.

With such a configuration, since the area of the component mounting region of the substrate 90 can be reduced, the amplifier circuit 10 can be reduced in size. In addition, the wiring connecting the inductors 31 and 32 and the midpoint of the input-side coil 211 can be shortened. Thus, the path for supplying the power supply voltage Vcc from the bypass capacitor 41 to the output ends of the amplifiers 11 and 12 can be shortened, so that the inductance component in the path can be reduced, and the impedance in the low frequency band can be further reduced.

The input-side coil 221 and the output-side coil 222 constituting the input transformer 22 are composed of planar conductors formed between the main surface 90a and the semiconductor IC 80. Assuming the main surface 90a is viewed in plan view, the input-side coil 221 and the output-side coil 222 at least partially overlap with each other.

The inductors 33 and 34 are composed of planar conductors formed between the main surface 90a and the semiconductor IC 80. Assuming the main surface 90a is viewed in plan view, each of the inductors 33 and 34 may be a coil having a meander shape, a spiral shape, or a linear shape.

It is sufficient that each of the input-side coil 221, the output-side coil 222, and the inductors 33 and 34 is at least partially formed at least on the main surface 90a or inside the substrate 90, for example, may be formed on a surface of the semiconductor IC 80 facing the main surface 90a.

Here, assuming the substrate 90 is viewed in plan view, the input-side coil 221, the output-side coil 222, and the inductors 33 and 34 overlap with the semiconductor IC 80.

With such a configuration, since the area of the component mounting region of the main surface 90a can be reduced, the amplifier circuit 10 can be reduced in size.

Alternatively, at least one of the input-side coil 221, the output-side coil 222, and the inductors 33 and 34 may be included in the semiconductor IC 80. With such a configuration, the amplifier circuit 10 can be reduced in size.

Further, the bypass capacitors 41 and 42 may alternatively be surface-mounted components disposed on the main surface 90a or 90b.

### [3. Effects and the Like]

As described above, the amplifier circuit 10 according to the present embodiment includes a high frequency input terminal 101 and a high frequency output terminal 102, amplifiers 11 and 12, an output transformer 21 having an input-side coil 211 and an output-side coil 212, inductors 31 and 32, and a bypass capacitor 41. The output end of the amplifier 11 is connected to one end of the input-side coil 211 and one end of the inductor 31. The output end of the amplifier 12 is connected to the other end of the input-side coil 211 and one end of the inductor 32. The other end of the inductor 31, the other end of the inductor 32, and one end of the bypass capacitor 41 are connected to the midpoint of the input-side coil 211. One end of the output-side coil 212 is connected to the high frequency output terminal 102. The other end of the bypass capacitor 41 and the other end of the output-side coil 212 are connected to the ground.

With such a configuration, since the inductor 31 is connected in parallel between one end and the midpoint of the input-side coil 211, the inductance component of a path from the bypass capacitor 41 to the output end of the amplifier 11 can be reduced. Also, since the inductor 32 is connected in parallel between the other end and the midpoint of the input-side coil 211, the inductance component of a path from the bypass capacitor 41 to the output end of the amplifier 12 can be reduced. Thus, the output impedance of the amplifiers 11 and 12 in a low frequency band such as the baseband can be reduced. Therefore, a differential amplification type amplifier circuit 10 in which the impedance in the low frequency band is reduced can be provided.

For example, the amplifier circuit 10 may further include a Vcc terminal 103 connected to the input-side coil 211.

With such a configuration, the inductance component of the path for supplying the power supply voltage Vcc from the bypass capacitor 41 to the output ends of the amplifiers 11 and 12 can be reduced.

For example, the amplifier circuit 10 may further include an input transformer 22 having an input-side coil 221 and an output-side coil 222, inductors 33 and 34, and a bypass capacitor 42, in which the input end of the amplifier 11 is connected to one end of the output-side coil 222 and one end of the inductor 33, the input end of the amplifier 12 is connected to the other end of the output-side coil 222 and one end of the inductor 34, the other end of the inductor 33, the other end of the inductor 34, and one end of the bypass capacitor 42 are connected to the midpoint of the output-side coil 222, one end of the input-side coil 221 is connected to the high frequency input terminal 101, and the other end of the bypass capacitor 42 and the other end of the input-side coil 221 are connected to the ground.

With such a configuration, since the inductor 33 is connected in parallel between one end and the midpoint of the output-side coil 222, the inductance component of a path from the bypass capacitor 42 to the input end of the amplifier 11 can be reduced. Also, since the inductor 34 is connected in parallel between the other end and the midpoint of the output-side coil 222, the inductance component of a path from the bypass capacitor 42 to the input end of the amplifier 12 can be reduced. Thus, the input impedance of the amplifiers 11 and 12 in a low frequency band such as the baseband can be reduced.

For example, the amplifier circuit 10 may further include a Vb terminal 104 connected to the output-side coil 222.

With such a configuration, the inductance component of the path for supplying the bias voltage Vb from the bypass capacitor 42 to the input ends of the amplifiers 11 and 12 can be reduced.

For example, the amplifier circuit 10A according to Variation 1 may further include a capacitor 44 connected between the other ends of the inductor 31 and inductor 32 and the ground.

With such a configuration, in addition to the inductors 31 and 32, by grounding the midpoint of the input-side coil 211 in a more high frequency manner by the capacitor 44, the impedance in a low frequency band such as the baseband can be further reduced, so that the memory effect can be further suppressed.

For example, the amplifier circuit 10A according to Variation 1 may further include a capacitor 45 connected between the other ends of the inductor 33 and inductor 34 and the ground.

With such a configuration, in addition to the inductors 33 and 34, by grounding the midpoint of the output-side coil 222 in a more high-frequency manner by the capacitor 45, the impedance in a low frequency band such as the baseband can be further reduced, so that the memory effect can be further suppressed.

For example, the amplifier circuit 10B according to Variation 2 may further include a first LC series circuit that is connected between the output end of the amplifier 11 and the ground and that is formed by connecting a inductor 35 and a capacitor 46 in series, and a second LC series circuit that is connected between the output end of the amplifier 12 and the ground and that is formed by connecting a inductor 36 and a capacitor 47 in series.

With such a configuration, since the high-order harmonic components can be short-circuited by the first LC series circuit and the second LC series circuit, particularly second-order harmonic components can be suppressed.

For example, the amplifier circuit 10 may further includes a substrate 90, in which at least a part of the output transformer 21 is formed at least inside the substrate 90 or on the surface of the substrate 90, each of the inductors 31 and 32 is a surface-mounted component disposed on the substrate 90, and assuming the substrate 90 is viewed in plan view, the inductors 31 and 32 are disposed in a region surrounded by the output transformer 21.

With such a configuration, since the area of the component mounting region of the substrate 90 can be reduced, the amplifier circuit 10 can be reduced in size. In addition, the wiring connecting the inductors 31 and 32 and the midpoint of the input-side coil 211 can be shortened. Thus, the path for supplying the power supply voltage Vcc from the bypass capacitor 41 to the output ends of the amplifiers 11 and 12 can be shortened, so that the inductance component in the path can be reduced, and the impedance in a low frequency band can be reduced.

For example, in the amplifier circuit 10, the amplifiers 11 and 12 may be included in a semiconductor IC 80 disposed on the substrate 90, in which at least a part of the input transformer 22, at least a part of the inductor 33, and at least a part of the inductor 34 are formed at least inside the substrate 90 or on the surface of the substrate 90, and assuming the substrate 90 is viewed in plan view, the input transformer 22 and the inductors 33 and 34 overlap with the semiconductor IC 80.

With such a configuration, since the area of the component mounting region of the substrate 90 can be reduced, the amplifier circuit 10 can be reduced in size.

For example, in the amplifier circuit 10, the amplifiers 11 and 12, the input transformer 22, and the inductors 33 and 34 may be included in the semiconductor IC 80 disposed on the substrate 90.

With such a configuration, the amplifier circuit 10 can be reduced in size.

Further, for example, the amplifier circuit 10C according to Variation 3 and the amplifier circuit 10D according to Variation 4 include a high frequency input terminal 101 and a high frequency output terminal 102, peak amplifiers 16 and 17, an output transformer 21b (or 21) having an input-side coil 211b (or 211) and an output-side coil 212b (or 212), inductors 31b and 32b, and a bypass capacitor 41, in which the output end of the peak amplifier 16 is connected to one end of the input-side coil 211b (or 211) and one end of the inductor 31b, the output end of the peak amplifier 17 is connected to the other end of the input-side coil 211b (or 211) and one end of the inductor 32b, the other end of the inductor 31b, the other end of the inductor 32b, and one end of the bypass capacitor 41 are connected to the midpoint of the input-side coil 211b (or 211), and one end of the output-side coil 212b (or 212) is connected to the high frequency output terminal 102, and the other end of the bypass capacitor 41 and the other end of the output-side coil 212 are connected to the ground. The amplifier circuits 10C and 10D may further include carrier amplifiers 14 and 15 and inductors 31a and 32a, in which the output end of the carrier amplifier 14 is connected to one end of the inductor 31a, the output end of the carrier amplifier 15 is connected to one end of the inductor 32a, and the other end of the inductor 31a and the other end of the inductor 32a are connected to one end of the bypass capacitor 41 and the input-side coil 211b (or 211).

With such a configuration, the inductance component of the path for supplying the power supply voltage Vcc from the bypass capacitor 41 to the output ends of the carrier amplifiers 14 and 15 can be reduced. Thus, the output impedance of the carrier amplifiers 14 and 15 in a low frequency band such as the baseband can be reduced. Further, the inductance component of the path for supplying the power supply voltage Vcc from the bypass capacitor 41 to the output ends of the peak amplifiers 16 and 17 can be reduced. Thus, the output impedance of the peak amplifiers 16 and 17 in a low frequency band such as the baseband can be reduced. Therefore, it is possible to provide a Doherty amplifier circuit in which the intermodulation distortion component generated by mixing the baseband with the fundamental wave band of the high frequency signal is suppressed, and the deterioration of the ACLR of the high frequency signal in the fundamental wave band is suppressed.

For example, the amplifier circuits 10C and 10D further include an input transformer 22b having an input-side coil 221b and an output-side coil 222b, inductors 33b and 34b, and a bypass capacitor 42b, in which the input end of the peak amplifier 16 is connected to one end of the output-side coil 222b and one end of the inductor 33b, the input end of the peak amplifier 17 is connected to the other end of the output-side coil 222b and one end of the inductor 34b, the other end of the inductor 33b, the other end of the inductor 34b, and one end of the bypass capacitor 42b are connected to the midpoint of the output-side coil 222b, one end of the input-side coil 221b is connected to the high frequency input terminal 101, and the other end of the bypass capacitor 42b and the other end of the input-side coil 221b are connected to the ground. The amplifier circuits 10C and 10D may further include an input transformer 22a having an input-side coil 221a and an output-side coil 222a, inductors 33a and 34a, and a bypass capacitor 42a, in which the input end of the carrier amplifier 14 is connected to one end of the output-side coil 222a and one end of the inductor 33a, the input end of the carrier amplifier 15 is connected to the other end of the output-side coil 222a and one end of the inductor 34a, the other end of the inductor 33a, the other end of the inductor 34a, and one end of the bypass capacitor 42a are connected to the output-side coil 222a, and the other end of the bypass capacitor 42a is connected to the ground.

With such a configuration, the inductance component of the path for supplying the bias voltage Vb1 from the bypass capacitor 42a to the input ends of the carrier amplifiers 14 and 15 can be reduced. Thus, the input impedance of the carrier amplifiers 14 and 15 in a low frequency band such as the baseband can be reduced. Further, the inductance component of the path for supplying the bias voltage Vb2 from the bypass capacitor 42b to the input ends of the peak amplifiers 16 and 17 can be reduced. Thus, the input impedance of the peak amplifiers 16 and 17 in a low frequency band such as the baseband can be reduced. Therefore, it is possible to provide a Doherty amplifier circuit in which the intermodulation distortion component generated by mixing the baseband with the fundamental wave band of the high frequency signal is suppressed, and the deterioration of the ACLR of the high frequency signal in the fundamental wave band is suppressed.

The communication device 4 according to the present embodiment includes the RFIC 3 that processes a high frequency signal, and the amplifier circuit 10 that transmits the high frequency signal between the RFIC 3 and the antenna 2.

With such a configuration, the effects of the amplifier circuit 10 can be realized in the communication device 4.

### Other Embodiments and the Like

The amplifier circuit and the communication device according to the embodiment of the present disclosure have been described with reference to the embodiment and the variations; however, the amplifier circuit and the communication device according to the present disclosure are not limited to the embodiment and the variations described above. The present disclosure also includes other embodiments realized by combining any components of the above embodiment and the variations, modified examples obtained by applying various modifications that a person skilled in the art can think of to the above embodiment and the variations without departing from the spirit of the present disclosure, and various apparatuses incorporating the above amplifier circuit and the communication device.

For example, in the amplifier circuit and the communication device according to the above embodiment and variations, other circuit elements and wiring may be inserted between the paths connecting the circuit elements and the signal paths disclosed in the drawings.

Features of the amplifier circuit and the communication device according to each of the above embodiments will be described below.

<1>

An amplifier circuit comprising:
a high frequency input terminal and a high frequency output terminal;
a first amplifying element and a second amplifying element;
an output transformer having a first input-side coil and a first output-side coil;
a first inductor and a second inductor; and
a first bypass capacitor,
wherein
an output end of the first amplifying element is connected to one end of the first input-side coil and one end of the first inductor,
an output end of the second amplifying element is connected to an other end of the first input-side coil and one end of the second inductor,
an other end of the first inductor, an other end of the second inductor, and one end of the first bypass capacitor are connected to the first input-side coil,
one end of the first output-side coil is connected to the high frequency output terminal, and
an other end of the first bypass capacitor and an other end of the first output-side coil are connected to a ground.
   <2>

The amplifier circuit according to <1>, further comprising:
a power supply voltage supply terminal connected to the first input-side coil.
   <3>

The amplifier circuit according to <1> or <2>, further comprising:
a first input transformer having a second input-side coil and a second output-side coil;
a third inductor and a fourth inductor; and
a second bypass capacitor,
wherein
an input end of the first amplifying element is connected to one end of the second output-side coil and one end of the third inductor,
an input end of the second amplifying element is connected to an other end of the second output-side coil and one end of the fourth inductor,
an other end of the third inductor, an other end of the fourth inductor, and one end of the second bypass capacitor are connected to the second output-side coil,
one end of the second input-side coil is connected to the high frequency input terminal, and
an other end of the second bypass capacitor and an other end of the second input-side coil are connected to the ground.
   <4>

The amplifier circuit according to <3>, further comprising:
a bias voltage supply terminal connected to the second output-side coil.
   <5>

The amplifier circuit according to any one of <1> to <4>, further comprising:
a first capacitor connected between the other ends of the first inductor and second inductor and the ground.
   <6>

The amplifier circuit according to <3> or <4>, further comprising:
a second capacitor connected between the other ends of the third inductor and fourth inductor and the ground.
   <7>

The amplifier circuit according to any one of <1> to <6>, further comprising:
a first LC series circuit that is connected between the output end of the first amplifying element and the ground and that is formed by connecting an inductor and a capacitor in series; and
a second LC series circuit that is connected between the output end of the second amplifying element and the ground and that is formed by connecting an inductor and a capacitor in series.
   <8>

The amplifier circuit according to <3> or <4>, further comprising:
a substrate,
wherein
at least a part of the output transformer is formed at least inside the substrate or on a surface of the substrate,
each of the first inductor and the second inductor is a surface-mounted component disposed on the substrate, and
assuming the substrate is viewed in plan view, the first inductor and the second inductor are disposed in a region surrounded by the output transformer.
   <9>

The amplifier circuit according to <8>, wherein
the first amplifying element and the second amplifying element are included in a semiconductor IC disposed on the substrate,
at least a part of the first input transformer, at least a part of the third inductor, and at least a part of the fourth inductor are formed at least inside the substrate or on the surface of the substrate, and
assuming the substrate is viewed in plan view, the first input transformer, the third inductor, and the fourth inductor overlap with the semiconductor IC.
   <10>

The amplifier circuit according to <8>, wherein the first amplifying element, the second amplifying element, the first input transformer, the third inductor, and the fourth inductor are included in a semiconductor IC disposed on the substrate.

<11>

The amplifier circuit according to any one of <1> to <10>, further comprising:
a third amplifying element and a fourth amplifying element; and
a fifth inductor and a sixth inductor,
wherein
an output end of the third amplifying element is connected to one end of the fifth inductor,
an output end of the fourth amplifying element is connected to one end of the sixth inductor, and
an other end of the fifth inductor and an other end of the sixth inductor are connected to the one end of the first bypass capacitor and the first input-side coil.
   <12>

The amplifier circuit according to <11>, further comprising:
a second input transformer having a third input-side coil and a third output-side coil;
a seventh inductor and an eighth inductor; and
a third bypass capacitor,
wherein
an input end of the third amplifying element is connected to one end of the third output-side coil and one end of the seventh inductor,
an input end of the fourth amplifying element is connected to an other end of the third output-side coil and one end of the eighth inductor,
an other end of the seventh inductor, an other end of the eighth inductor, and one end of the third bypass capacitor are connected to the third output-side coil, and
an other end of the third bypass capacitor is connected to the ground.
   <13>

A communication device comprising:
a signal processing circuit that processes a high frequency signal; and
the amplifier circuit according to any one of <1> to <12> that transmits the high frequency signal between the signal processing circuit and an antenna.

### INDUSTRIAL APPLICABILITY

The present disclosure, as an amplifier circuit and a communication device arranged in a front-end section, can be widely used in communication devices such as cellular phones.

### REFERENCE SIGNS LIST

1 high frequency circuit
2 antenna
3 RF signal processing circuit (RFIC)
4 communication device
10, 10A, 10B, 10C, 10D, 510 amplifier circuit
11, 12 amplifier
13, 18, 19 preamplifier
14, 15 carrier amplifier
16, 17 peak amplifier
21, 21a, 21b output transformer
22, 22a, 22b input transformer
31, 31a, 31b, 32, 32a, 32b, 33, 33a, 33b, 34, 34a, 34b,
35, 36, 37, 38 inductor
41, 42, 42a, 42b bypass capacitor
43, 44, 45, 46, 47, 48, 49a, 49b capacitor
51, 54 switch
52, 53 filter
60 phase shift circuit
61, 62 LC series resonance circuit
80 semiconductor IC
90 substrate
90a, 90b main surface
100 antenna connection terminal
101 high frequency input terminal
102 high frequency output terminal
103 Vcc terminal
104, 104a, 104b Vb terminal
211, 211a, 211b, 221, 221a, 221b input-side coil
212, 212a, 212b, 222, 222a, 222b output-side coil

1. An amplifier circuit comprising:
a high frequency input terminal and a high frequency output terminal;
a first amplifying element and a second amplifying element;
an output transformer having a first input-side coil and a first output-side coil;
a first inductor and a second inductor; and
a first bypass capacitor,
wherein
an output end of the first amplifying element is connected to one end of the first input-side coil and one end of the first inductor,
an output end of the second amplifying element is connected to an other end of the first input-side coil and one end of the second inductor,
an other end of the first inductor, an other end of the second inductor, and one end of the first bypass capacitor are connected to the first input-side coil,
one end of the first output-side coil is connected to the high frequency output terminal, and
an other end of the first bypass capacitor and an other end of the first output-side coil are connected to a ground.

2. The amplifier circuit according to claim 1, further comprising:
a power supply voltage supply terminal connected to the first input-side coil.

3. The amplifier circuit according to claim 2, further comprising:
a first input transformer having a second input-side coil and a second output-side coil;
a third inductor and a fourth inductor; and
a second bypass capacitor,
wherein
an input end of the first amplifying element is connected to one end of the second output-side coil and one end of the third inductor,
an input end of the second amplifying element is connected to an other end of the second output-side coil and one end of the fourth inductor,
an other end of the third inductor, an other end of the fourth inductor, and one end of the second bypass capacitor are connected to the second output-side coil,
one end of the second input-side coil is connected to the high frequency input terminal, and
an other end of the second bypass capacitor and an other end of the second input-side coil are connected to the ground.

4. The amplifier circuit according to claim 3, further comprising:
a bias voltage supply terminal connected to the second output-side coil.

5. The amplifier circuit according to any claim 4, further comprising:
a first capacitor connected between the other ends of the first inductor and second inductor and the ground.

6. The amplifier circuit according to claim 4, further comprising:
a second capacitor connected between the other ends of the third inductor and fourth inductor and the ground.

7. The amplifier circuit according to claim 6, further comprising:
a first LC series circuit that is connected between the output end of the first amplifying element and the ground and that is formed by connecting an inductor and a capacitor in series; and
a second LC series circuit that is connected between the output end of the second amplifying element and the ground and that is formed by connecting an inductor and a capacitor in series.

8. The amplifier circuit according to claim 4, further comprising:
a substrate,
wherein
at least a part of the output transformer is formed at least inside the substrate or on a surface of the substrate,
each of the first inductor and the second inductor is a surface-mounted component disposed on the substrate, and
assuming the substrate is viewed in plan view, the first inductor and the second inductor are disposed in a region surrounded by the output transformer.

9. The amplifier circuit according to claim 8, wherein
the first amplifying element and the second amplifying element are included in a semiconductor IC disposed on the substrate,
at least a part of the first input transformer, at least a part of the third inductor, and at least a part of the fourth inductor are formed at least inside the substrate or on the surface of the substrate, and
assuming the substrate is viewed in plan view, the first input transformer, the third inductor, and the fourth inductor overlap with the semiconductor IC.

10. The amplifier circuit according to claim 8, wherein the first amplifying element, the second amplifying element, the first input transformer, the third inductor, and the fourth inductor are included in a semiconductor IC disposed on the substrate.

11. The amplifier circuit according to claim 10, further comprising:
a third amplifying element and a fourth amplifying element; and
a fifth inductor and a sixth inductor,
wherein
an output end of the third amplifying element is connected to one end of the fifth inductor,
an output end of the fourth amplifying element is connected to one end of the sixth inductor, and
an other end of the fifth inductor and an other end of the sixth inductor are connected to the one end of the first bypass capacitor and the first input-side coil.

12. The amplifier circuit according to claim 11, further comprising:
a second input transformer having a third input-side coil and a third output-side coil;
a seventh inductor and an eighth inductor; and
a third bypass capacitor,
wherein
an input end of the third amplifying element is connected to one end of the third output-side coil and one end of the seventh inductor,
an input end of the fourth amplifying element is connected to an other end of the third output-side coil and one end of the eighth inductor,
an other end of the seventh inductor, an other end of the eighth inductor, and one end of the third bypass capacitor are connected to the third output-side coil, and
an other end of the third bypass capacitor is connected to the ground.

13. A communication device comprising:
a signal processing circuit that processes a high frequency signal; and
the amplifier circuit according to claim 12 that transmits the high frequency signal between the signal processing circuit and an antenna.

14. The amplifier circuit according to claim 1, further comprising:
a first input transformer having a second input-side coil and a second output-side coil;
a third inductor and a fourth inductor; and
a second bypass capacitor,
wherein
an input end of the first amplifying element is connected to one end of the second output-side coil and one end of the third inductor,
an input end of the second amplifying element is connected to an other end of the second output-side coil and one end of the fourth inductor,
an other end of the third inductor, an other end of the fourth inductor, and one end of the second bypass capacitor are connected to the second output-side coil,
one end of the second input-side coil is connected to the high frequency input terminal, and
an other end of the second bypass capacitor and an other end of the second input-side coil are connected to the ground.

15. The amplifier circuit according to claim 14, further comprising:
a bias voltage supply terminal connected to the second output-side coil.

16. The amplifier circuit according to any claim 15, further comprising:
a first capacitor connected between the other ends of the first inductor and second inductor and the ground.

17. The amplifier circuit according to claim 3, further comprising:
a second capacitor connected between the other ends of the third inductor and fourth inductor and the ground.

18. The amplifier circuit according to claim 17, further comprising:
a first LC series circuit that is connected between the output end of the first amplifying element and the ground and that is formed by connecting an inductor and a capacitor in series; and
a second LC series circuit that is connected between the output end of the second amplifying element and the ground and that is formed by connecting an inductor and a capacitor in series.

19. The amplifier circuit according to claim 3, further comprising:
a substrate,
wherein
at least a part of the output transformer is formed at least inside the substrate or on a surface of the substrate,
each of the first inductor and the second inductor is a surface-mounted component disposed on the substrate, and
assuming the substrate is viewed in plan view, the first inductor and the second inductor are disposed in a region surrounded by the output transformer.

20. The amplifier circuit according to claim 19, wherein
the first amplifying element and the second amplifying element are included in a semiconductor IC disposed on the substrate,
at least a part of the first input transformer, at least a part of the third inductor, and at least a part of the fourth inductor are formed at least inside the substrate or on the surface of the substrate, and
assuming the substrate is viewed in plan view, the first input transformer, the third inductor, and the fourth inductor overlap with the semiconductor IC.
